(19) United States
(12) Patent Application Publication
(10) Pub. No.: US 2005/0281013 A1
(43) Pub. Date: Dec. 22, 2005

(54) Removable ribs in a chassis housing to accommodate extra-wide printed circuit board assemblies

(76) Inventors: Thomas J. Carullo, Marlton, NJ (US); Arthur G. Willers, Delran, NJ (US)

Correspondence Address: BECK AND TYSVER P.L.L.C., 2900 THOMAS AVENUE SOUTH, SUITE 100, MINNEAPOLIS, MN, 55416, US

(21) Appl. No.: 10/872,718

(22) Filed: Jun. 21, 2004

(51) Int. Cl. H05K 5/00; H05K 9/00

(52) U.S. Cl. 361/796; 361/818; 174/35 GC

(57) ABSTRACT

A flexible slotting system in a chassis easily accommodates printed circuit board assemblies having varying widths. A rib assembly is removably attached to the chassis frame to yield slots of the desired width. EMC gaskets over the entire length of the rib to prevent electromagnetic energy from leaking from the chassis.

### FIELD OF THE INVENTION

The present invention relates generally to a chassis for housing printed circuit board assemblies and more particularly to a removable rib assembly for such a chassis and to a method of modifying the size of slots in the chassis to accommodate printed circuit boards of varied widths.

### BACKGROUND OF THE INVENTION

A chassis for supporting printed circuit boards typically includes a number of predetermined slots into which printed circuit boards of given widths are inserted. A printed circuit board assembly includes a printed circuit board mounted to a face plate. The PCB assembly can be “single-wide” and include a single printed circuit board; or it may be “extra-wide” and two or more parallel, spaced-apart printed circuit boards, mounted to the same face plate. Typically, a chassis provides predetermined slots, arranged in one or more arrays, for receiving and supporting printed circuit boards. It is further typical for such a slot to be unalterably sized at manufacture to accommodate a single-wide to accommodate a single-wide PCB assembly or double-wide to accommodate a double-wide PCB assembly. In other words, the slots are of a predetermined, unalterable size to receive a particular size of printed circuit board. Because the slots are width-specific, the chassis provides little flexibility with respect to positioning and locating PCB assemblies in the chassis during assembly of components in the chassis or in the field.

A more flexible slotting system would be desirable so that a chassis can easily accommodate PCB assemblies in any location on the chassis regardless of their width. Further, it would be desirable for the flexible slotting system to allow modification of slots (from single-wide to double-wide or extra-wide or vice versa or extra high component PCB) post-manufacture or in the field. Still further, it would be desirable for the flexible slotting system to provide shielding against leaks of electromagnetic energy.

### SUMMARY OF THE INVENTION

A chassis according to the present invention incorporates a flexible slotting system that achieves these and other objections.

A chassis frame defines an opening or aperture for receiving and supporting printed circuit board assemblies. A removable rib assembly, when selectively installed, spans the opening and establishes two adjacent slots for receiving independent printed circuit board assemblies. When the rib assembly is removed, the opening accommodates a printed circuit board assembly having more than one printed circuit board or a single printed circuit board who components are extraordinary tall as not to fit into a single slot location.

The rib is preferably of unitary construction. The rib has, however, several notable features or areas which will be independently identified. The rib has an elongate rib body integral with or connected to a face plate that is generally perpendicular thereto. Tabs extend from the ends of the face plate and define screw holes therethrough.

The chassis frame defines an opening, and the rib face plate is sized to span the opening and overlap with the frame. Aligned holes in the chassis on opposite sides of the opening match the holes on the tabs of the rib assembly. The chassis frame is recessed immediately adjacent the screw holes, with the recess sized to accommodate the tabs such that the tabs do not protrude beyond the chassis frame when the rib assembly is installed.

The tab is preferably recessed immediately adjacent its hole, so that a screw head sits flush with or below the surface of the face plate.

An electromagnetic containment gasket covers the entire length of the rib including the mating joint between the rib assembly and the chassis frame to prevent leaking of electromagnetic energy from inside the chassis to the environment.

The rib is a standard part, that is interchangeable in all locations from the initial intended location.

### BRIEF DESCRIPTION OF THE DRAWINGS

An exemplary version of a flexible slotting system is shown in the figures wherein like reference numerals refer to equivalent structure throughout, and wherein:

FIG. 1 is a partial perspective view of a chassis including a slotting system with removable rib assemblies, with one rib assembly expoded exploded from the chassis;

FIG. 2 is a schematic illustrating single- and double-wide printed circuit board assemblies, along with a single printed circuit board with extraordinarily high components mounted to it;

FIG. 3 is an enlarged partial perspective view of the area of the frame of the chassis that mates with a removable rib assembly;

FIG. 4 is a cross-section side view taken along line 4-4 of FIG. 6 of a portion the slotting system and removable rib assembly mounted in a chassis;

FIG. 5 is an enlarged cross-sectional side view of a portion of the slotting system illustrated in FIG. 4;

FIG. 6 is perspective view of a chassis with printed circuit board assemblies supported therein, with two printed circuit board assemblies exploded from the chassis;

FIG. 7 is a front view of a chassis populated with printed circuit board assemblies with portions cut away to reveal removable rib assemblies in association with a single-wide board assembly and the absence of a rib assembly in association with a double-wide board assembly or a single printed circuit board with extraordinarily high components mounted to it; and

FIG. 8 is an example of an extra-wide printed circuit board assembly having a single printed circuit board with extra-high components attached thereto.

### DETAILED DESCRIPTION OF PREFERRED EMBODIMENT(S)

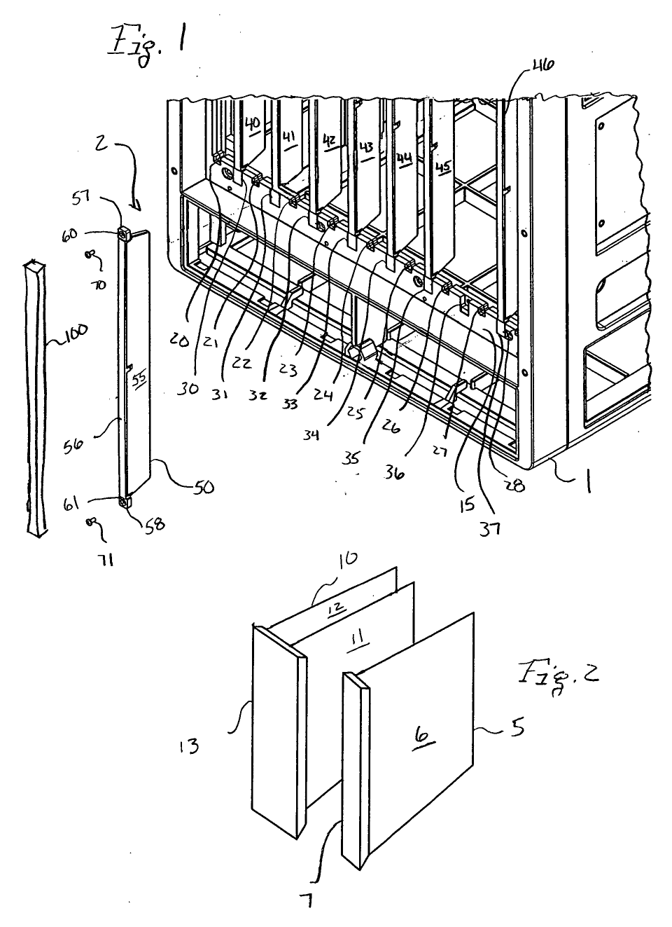

A chassis is configured to receive and support an array of parallel, spaced-apart printed circuit board assemblies in predetermined locations. FIG. 1 shows such a chassis 1 empty, with no printed circuit board assemblies installed. The chassis 1 illustrated in FIG. 1 incorporates a flexible slotting system 2. A similar chassis is described in U.S. Ser. No. ______, filed Jun. 21, 2004, entitled Modular Chassis Divided Along a Midplane and Cooling System Therefor, and is hereby incorporated by reference.

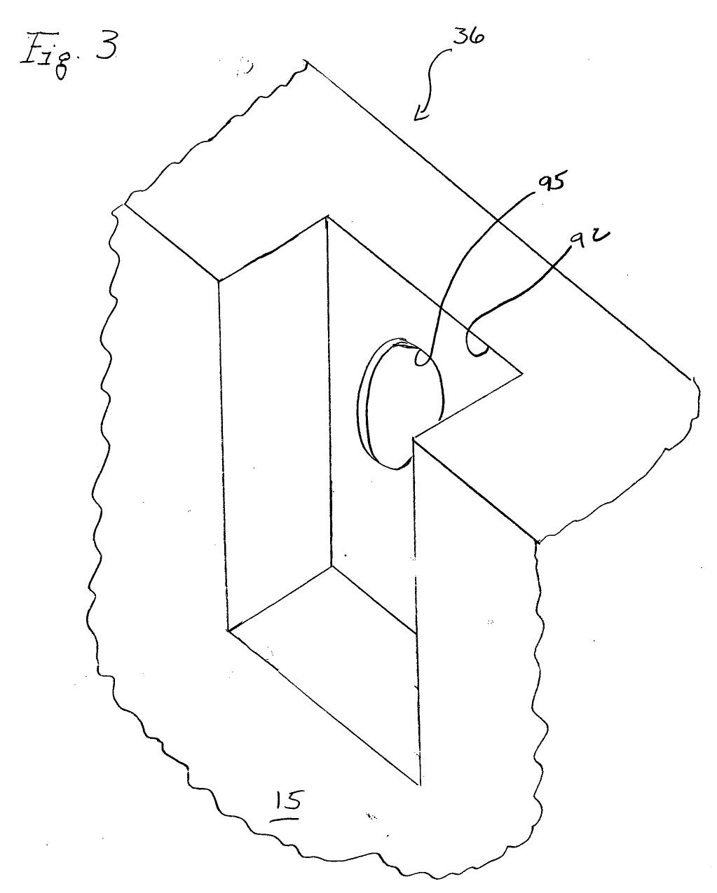

Two kinds of printed circuit board (PCB) assemblies are illustrated in FIG. 2. PCB assembly 5 is a “single-wide” and includes one printed circuit board 6 connected to a face plate 7 that extends generally perpendicular to the printed circuit board 6. Printed circuit board assembly 10 is a “double-wide” and includes two spaced-apart, parallel printed circuit boards 11, 12, both connected to a face plate 13 that extends generally perpendicular to the printed circuit boards 11, 12. A third kind of printed circuit board assembly is illustrated in FIG. 8. PCB assembly 205 has a single printed circuit board 206 connected to a face plate 207. Particularly wide or high components 208, 209 are attached to PCB 206.

As shown in FIG. 1, the chassis 1 includes a frame 15 on a face of the chassis 1. The frame 15 defines one or more grooves into which the printed circuit boards (e.g. 6, 11, 12) of printed circuit board assemblies slide. The chassis 1 of FIG. 1 includes nine such grooves 20, 21, 22, 23, 24, 25, 26, 27, 28. Between adjacent grooves are rib-receiving positions 30, 31, 32, 33, 34, 35, 36, 37, 38. As described in greater detail below, the ribs can be selectively installed or removed to yield either single-wide or double-wide (or extra-wide) card slots to receive printed circuit board assemblies of matching size, or a single printed circuit board with extraordinarily high components mounted to it;

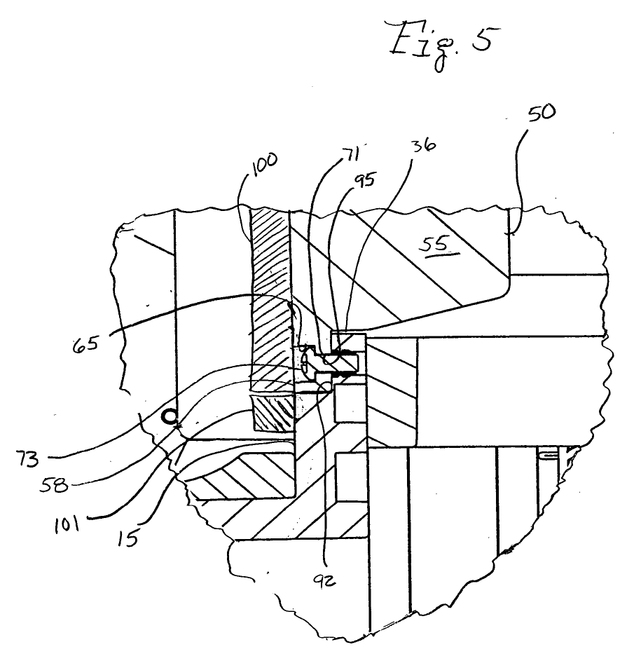

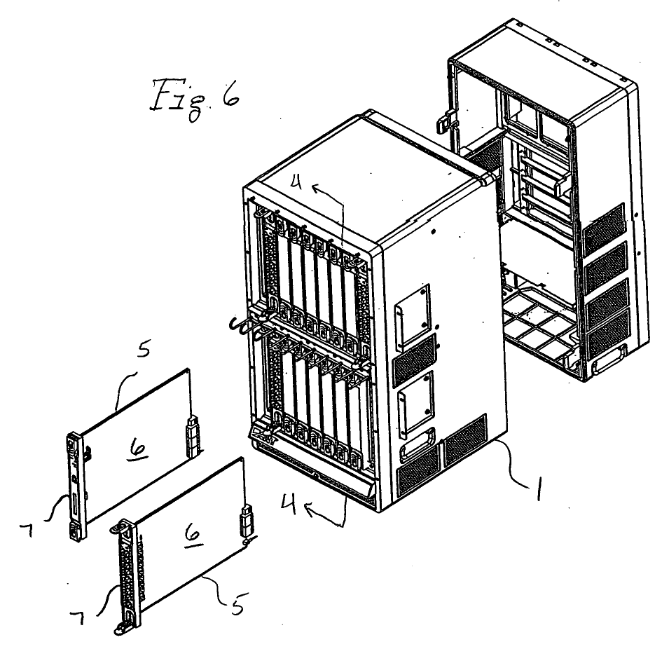

Seven rib assemblies 40, 41, 42, 43, 44, 45, 46 are illustrated in installed positions 30, 31, 32, 33, 34, 35, 37 on the chassis 1. An eighth representative rib assembly 50 is shown exploded from position 36. The rib, though a single unitary piece, includes several features of note. The rib assembly 50 includes an elongate rib body 55 connected to a face plate 56. The face plate 56 extends lengthwise beyond the rib body 55, terminating in tabs 57, 58. Each tab 57, 58 defines a sunken screw hole 60, 61. The sunken quality of the screw hole 60, 61 is not apparent from FIG. 1, but is shown in FIGS. 4 and 5. The tabs 57, 58 each define a recess 65 sized to accommodate the head of a screw.

Also illustrated in the exploded rib assembly 50, FIG. 1, are screws 70, 71, each having a head 72, 73 larger than a body 74, 75.

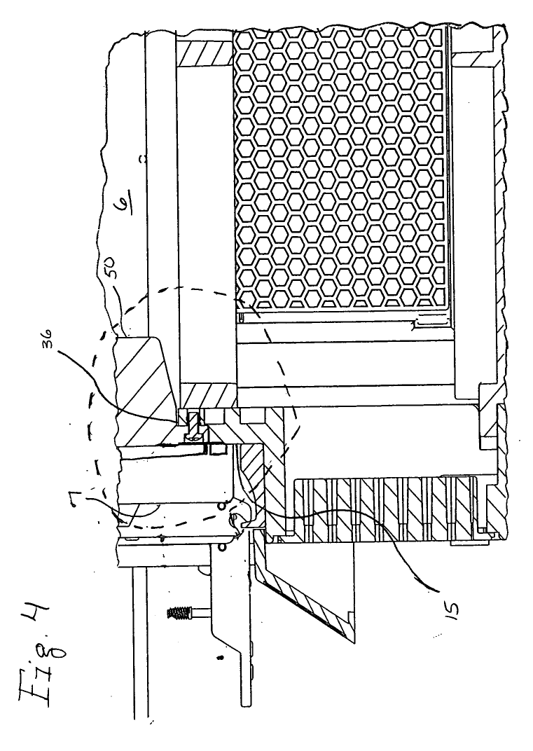

The structure of each rib-receiving position 30-38 is apparent from unfilled, but representative, position 36 illustrated in detail in FIG. 3. The frame 15 defines a recess 92 for receiving the tabs 57, 58 of a rib assembly 50. The frame further defines a screw hole 95 within the recess 92.

FIG. 4 shows a portion of rib assembly 50 installed on the chassis 1. FIG. 5 is an enlarged view of the joint and surrounding area. As shown in FIGS. 4 and 5, a rib assembly is installed with tab 58 seated in recess 92 defined in the frame 15. Screw 71 extends through screw hole 61 and into screw hole 95 in the frame 15 to secure the rib assembly 50 to the chassis 1. The recess 92 yields an assembly that is flush with the chassis frame 15.

FIG. 5 illustrates two gaskets 100, 101 which will be described further below.

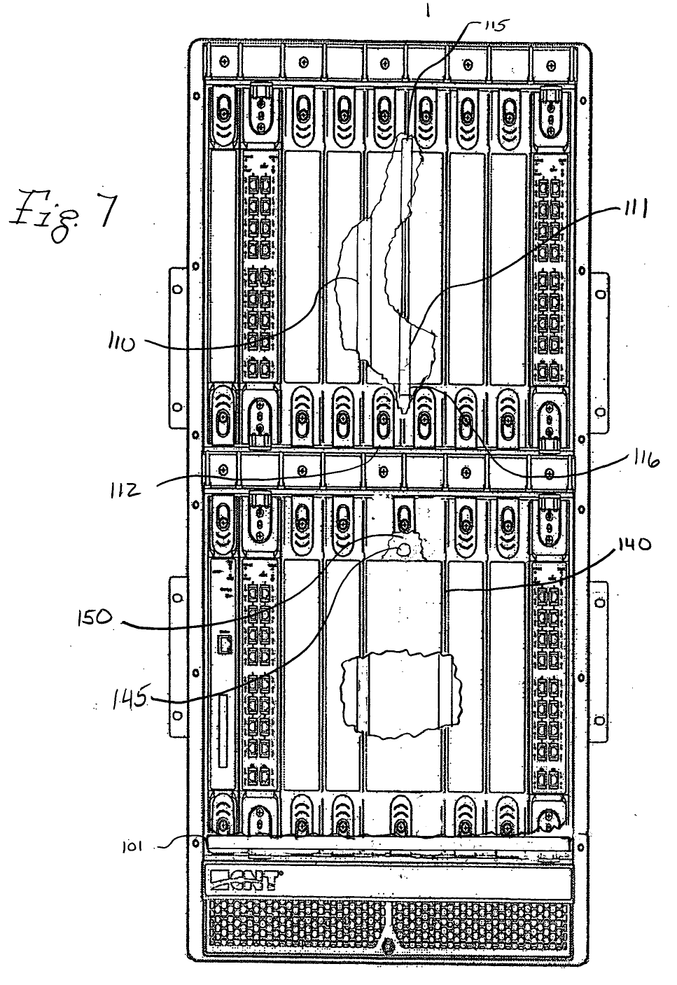

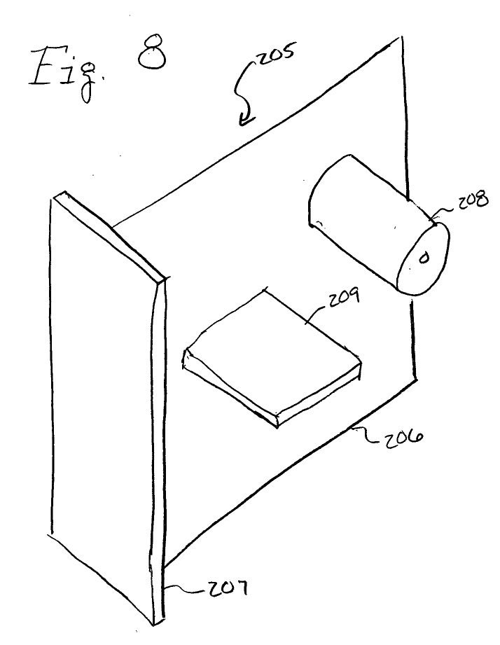

FIGS. 6 and 7 illustrate an entire chassis 1 housing two arrays of printed circuit board assemblies. Each array in the pictured chassis 1 of FIG. 6 includes nine printed circuit board assemblies. Via grooves (like grooves 30-37 of FIG. 1) and installed rib assemblies (like assemblies 40-46 and 50 described above with regard to FIG. 1), the chassis 1 thus defines eighteen predetermined slots or positions 100 for receiving printed circuit boards. All of the printed circuit board assemblies pictured in FIG. 6 are single-wide. FIG. 7 illustrates sixteen single-wide printed circuit board assemblies 5 and one double-wide assembly 10. (Assembly 10 might, alternatively, be an single printed circuit board with extra tall components.)

Cut-away portions in FIG. 7 reveal the installed rib assemblies 110, 111 in the upper array yielding slots to accommodate single-wide printed circuit board assembly 112. The electromagnetic containment gasket 100 (not illustrated in FIG. 7, but shown in FIGS. 1 and 5) covers a joint between the a rib assemblies 110 and the chassis frame 120. Cut-away portions of the lower array reveal the absence of the rib assembly in association with a double-wide assembly, or a assembly that has extra high components mounted on the PCB. 140. Screw hole 145 is defined by the surrounding frame 150. another cut-away portion of the lower array reveals one or four horizontally-extending, across the face of the chassis, electromagnetic containment gaskets 101. Three other gaskets (not shown) like gasket 101 are positioned at the upper end of the lower array and along the bottom and top of the upper array, such that each end of each printed circuit board assembly abuts a portion of a horizontally-extending gasket.

While the rib assembly has been described as if its components (face, body, tabs) are discrete items joined together, the rib assembly is preferably unitary and is molded, metallized plastic. The metallization provides EMC shielding.

It will also be noted that when installed, the face plate of the printed circuit board assembly overlaps or abuts the face plate or plane of the rib assembly and the chassis frame, such that the face plate of the printed circuit board entirely covers the opening of the chassis slot. Preferably, an EMC gasket is sandwiched between the face plate of the printed circuit board and the face plate of the rib assembly and the chassis frame such that electromagnetic energy does not leak from the chassis.

Although an illustrative version of the device is shown, it should be clear that many modifications to the device may be made without departing from the scope of the invention. For example, the slotting system and rib assembly of the present invention may be incorporated in a chassis housing any number greater than one of printed circuit board assemblies. In other words, the chassis might have slots for just two printed circuit board assemblies, and these slots may be divided by a removable rib assembly. Further, it will be apparent that the flexibility of the slotting system can accommodate printed circuit boards that are triple-wide or larger. To accommodate a triple-wide board, for example, one would simply remove two adjacent rib assemblies or leave them empty.

1.) A chassis for housing printed circuit board assemblies, comprising:
a) a chassis frame defining an opening for receiving printed circuit boards;
b) a rib assembly for dividing said opening into two slots for receiving two printed circuit board assemblies or a single printed circuit board with extraordinarily high components mounted to it;, said rib being removably connected to the chassis wall, such that by removing said rib from said wall, two adjacent slots become one slot to receive a printed circuit board assembly including two spaced apart printed circuit boards.

2. A chassis according to claim 1, wherein said rib assembly includes:
i) an elongate rib body;
ii) tabs projecting beyond the ends of the rib body, said tabs defining holes therethrough for receiving a screw.

3. A chassis according to claim 1, wherein said chassis frame defines a pair of associated screw holes adjacent opposite sides of said opening, the location of said screw holes forming a predetermined position for removable attachment of said rib assembly to said chassis frame.

4. A chassis according to claim 2, wherein said chassis frame defines a pair of associated screw holes adjacent opposite sides of said opening, the location of said screw holes forming a predetermined position for removable attachment of said rib assembly to said chassis frame.

5. A chassis according to claim 4, further comprising:
c) screws extending through said holes defined in said tabs on said rib assembly and into said holes in said chassis frame.

6. A chassis according to claim 5, further comprising:
d) an electromagnetic compliance gasket covering entire length (including over lapping at each end) of rib including two said screws, opposite end of said rib.

7. A chassis according to claim 4, wherein said frame defines a recessed notch for receiving said tabs on said rib assembly, such that said tabs do not protrude from said frame.

8. A chassis according to claim 7, wherein said tab hole is recessed for receiving a screw head, such that the screw head lies flush with the surface of the tab when the screw is fully installed.

9. A chassis according to claim 8 further comprising:
d) an electromagnetic compliance gasket covering entire length of rib including said screws on either end of said rib, and wherein said recessed notch in said chassis frame is sufficiently deep to accommodate said tab such that said rib assembly does not protrude from said chassis frame when connected thereto.

10. A method of converting a two adjacent single-wide slots to a single double-wide slot in a chassis for supporting printed circuit board assemblies, comprising the steps of:
a) providing a chassis frame defining an opening, said opening being divided into two slots, each for receiving a single printed circuit board, by a removable rib assembly; and
b) removing said rib assembly.

11. A method of converting a single double-wide slot to two adjacent single-wide slots in a chassis for supporting printed circuit board assemblies, comprising the steps of:
a) providing a chassis frame defining an opening;
b) removably attaching a rib assembly to said chassis frame, said rib assembly spanning said opening such that said opening is divided into two slots, each for receiving a single printed circuit board, by said removable rib assembly.

12. A method according to claim 11, wherein said rib assembly is removably attached to said chassis frame via screws.

13. A method according to claim 11, further comprising the step of:
c) covering the entire length of the rib including joints between the rib assembly and the chassis frame with an electromagnetic compliance gasket.

14. A method according to claim 13, wherein said gasket is adhesively attached to said rib and joints.
